(19) United States
(12) Patent Application Publication
(10) Pub. No.: US 2006/0071213 A1
(43) Pub. Date: Apr. 6, 2006

(54) Low temperature selective epitaxial growth of silicon germanium layers

(76) Inventors: Ce Ma, Cary, NC (US); Qing Min Wang, Edison, NJ (US)

Correspondence Address: David A. Hey;The BOC Group, Inc., Legal Services-IP, 575 Mountain Ave., Murray Hill, NJ, 07974, US

(21) Appl. No.: 10/957,791

(22) Filed: Oct. 4, 2004

(51) Int. Cl. H01L 29/12; H01L 21/20

(52) U.S. Cl. 257/65; 438/478; 257/616

(57) ABSTRACT

The present invention relates generally to a method and means for growing strained or relaxed or graded silicon germanium (SiGe) layers on a semiconductor substrate using a selective epitaxial growth process. In particular, the present invention provides a method for epitaxially growing SiGe layers at temperatures lower than 600° C. by using halogermane and silane precursor materials.

### FIELD OF THE INVENTION

The present invention relates generally to a method and means for growing strained or relaxed or graded silicon germanium (SiGe) layers on a semiconductor substrate using a low temperature selective epitaxial growth process.

### BACKGROUND

Selective epitaxial growth (SEG) is a known method for selectively growing a homogeneous or heterogeneous semiconductor layer only in a desired location over an exposed semiconductor surface, while avoiding growth over a surface area that has been masked with an oxide or nitride layer.

In particular, SEG has been used to grow SiGe layers on crystalline substrates, such as single crystalline silicon substrates, while growth on amorphous surfaces, areas masked typically with SiO₂ or Si₃N₄, is inhibited. In other words, the SiGe layer is selectively grown only on the portion of the silicon substrate surface that is exposed through windows in the mask layer. Grown SiGe layers can be either strained or relaxed or graded.

Prior art methods of growing SiGe layers rely on the use of chlorosilanes and germanes as the source gases (vapors) for the deposited layer. In particular, SiGe layers may be deposited using dichlorosilane and germane as the precursor materials in accordance with the following chemical reaction equation.
SiH₂Cl₂+GeH₄→SiGe+2HCl+2H₂

However, use of such precursor gases requires processing at relatively high temperatures; i.e. higher than 600° C., and generally between 600° C. and 900° C. because of the high thermal stability of hydrochlorosilanes. The need to employ such high temperatures not only adds heating costs in the method of depositing such layers, but can be detrimental to the target wafer.

Therefore, there remains a need in the art for improvements in the field of selective epitaxial growth of silicon germanium semiconductor layers.

### SUMMARY OF THE INVENTION

The present invention overcomes the problems associated with SiGe layer deposition that occur in the prior art. In particular, the present invention provides a method and means for low temperature selective epitaxy of SiGe layers on semiconductor substrates. The low thermal budget processes of the present invention used in depositing selective SiGe layers improves device performance and reduces production cost.

### DETAILED DESCRIPTION OF THE INVENTION

In accordance with the present invention, by using different source gases for the epitaxial growth, it is possible to grow SiGe layers at significantly lower temperatures than those employed in the prior art.

The present invention utilizes halogermanes and silanes as the source gases in order to grow the SiGe layers at temperatures below 600° C. These gases replace the chlorosilanes and germanes of the prior art. In accordance with the present invention, SiGe layers are deposited using halogermanes and silanes as the precursor materials in accordance with the following chemical reaction equation.
GeH₂Cl₂+SiH₄→SiGe+2HCl+2H₂

The deposition temperature for the above reaction is considerably lower than that required in the prior art as will be shown in the examples below.

The halogermanes that can be utilized in the present invention include, but are not limited to, those having the following formula.
X₄₋ₙGeHₙ, where X is F, Cl, Br, or I, and n is 0 to 3.

Specific examples that meet the above formula include chlorogermane, dichlorogermane, and trichlorogermane.

In addition, halogermanes that can be used in the present invention include halodigermanes of the formula
X₃₋ₘHₘGeGeHₙX₃₋ₙ, where X is F, Cl, Br, or I, m is 0 to 3 and n is 0 to 3;
organogermanes of the formula
R₄₋ₙGeHₙ, where R is a hydrocarbon group, and n is 0 to 3; and
organogermanium halides of the formula
R₄₋ₙGeXₙ, where R is a hydrocarbon group, X is F, Cl, Br, or I, and n is 1 to 3.

The method and means of the present invention also includes the optional addition of a further chlorine source, such as Cl₂ or HCl.

Silanes that are useful in the method and means of the present invention include, but are not limited to, silane (SiH₄), disilane (Si₂H₆), trisilane (Si₃H₈), other higher order silanes, and organosilanes of the formula
R₄₋ₙSiHₙ, where R is a hydrocarbon group, and n is 0 to 3.

The present invention is also applicable to the selective epitaxial growth of SiGeC layers, for which a source of carbon must also be provided. In particular, the present invention can utilize any suitable carbon source, such as monomethylsilane (CH₃SiH₃) and other organosilanes.

Because the halogermanes used in the present invention have a lower decomposition temperature than the hydrochlorosilanes of the prior art, the epitaxial deposition can be carried out at lower temperatures than those necessary for the prior art methods. In particular, the method and means of the present invention operates in a temperature range of 100° C. to 1000° C., preferably 400° C. to 600° C.

One advantage of the present invention is that the same selective epitaxial growth achieved by prior art methods, can still be accomplished, using the same hardware configurations. Therefore, no addition capital cost will be incurred and because the heating requirements are less, lower process costs may be realized. Further, the lower temperatures needed in accordance with the present invention reduce the risk of damage to under-layer and dopant profiles of the target wafers.

In this light, standard epitaxial growth chambers can be used, such as the AMAT Epi Centura and Epsilon 2000 ASM CVD systems. These chambers may be configured and set up to operate in conjunction with cleaning chambers, capping layer deposition chambers, etc. The present invention is applicable to any standard epitaxial growth process, including ultra-high vacuum CVD (UHV-CVD), low-pressure CVD (LPCVD), reduced-pressure CVD (RPCVD), rapid thermal CVD (RTCVD), and molecular beam epitaxy (MBE) processes.

Further, the SiGe or SiGeC layers of the present invention may be grown on crystalline substrates, such as single crystalline silicon substrates, a silicon layer formed on an insulator (SOI) substrate or layer, or selectively grown on silicon surfaces exposed through an amorphous surface such as a mask of SiO₂ or Si₃N₄.

The following examples are provided to show results achieved by the method and means of the present invention, but are not intended to limit the scope of the present invention.

### EXAMPLE 1

A CVD chamber is baked and pumped down to base pressure below 10⁻⁶ Torr. Dichlorogermane (GeH₂Cl₂) and silane (SiH₄) are then delivered to the CVD chamber at a continuous rate between 1 sccm and 1000 sccm. A masked silicon wafer substrate present in the CVD chamber is heated to a temperature between 100° C. to 1000° C., preferred 400° C. to 600° C. and the CVD chamber pressure is held between 1 mTorr and 10 Torr. An epitaxial Si₁₋ₓGeₓ (x=0 to 0.5) was selectively grown on exposed portions of the silicon wafer surface.

### EXAMPLE 2

In a similar process as described in example 1, a carbon source such a methylsilane or hydrocarbon, is also delivered to the CVD chamber. An epitaxial layer of Si_{1-x-y}GeₓC_{y} (x=0 to 0.5, y=0 to 0.3) was selectively grown on exposed portions of the silicon wafer surface.

### EXAMPLE 3

In a similar process as described in example 1, a relaxed and graded layer of Si₁₋ₓGeₓ (x=0 to 0.5) was selectively grown on exposed portions of the silicon wafer surface. A strained silicon layer is then deposited on the relaxed Si₁₋ₓGeₓ surface.

It is anticipated that other embodiments and variations of the present invention will become readily apparent to the skilled artisan in the light of the foregoing description and examples, and it is intended that such embodiments and variations likewise be included within the scope of the invention as set out in the appended claims.

1. A method for forming a SiGe layer on a semiconductor substrate, said method comprising:
providing a deposition chamber having said semiconductor substrate located therein;
introducing a halogermane precursor gas as a source material for germanium to said chamber;
introducing a silane precursor gas as a source material for silicon to said chamber;
reacting said halogermane precursor and said silane precursor to create SiGe;
depositing said SiGe on to said semiconductor substrate.

2. A method according to claim 1, wherein said step of reacting is carried out in a temperature range of 100° C. to 1000° C.

3. A method according to claim 2, wherein said temperature range is 400° C. to 600° C.

4. A method according to claim 1, wherein said step of reacting is carried out at a temperature below 600° C.

5. A method according to claim 1, wherein said halogermane is a halogermane according to the formula X₄₋ₙGeHₙ, where X is F, Cl, Br, or I, and n is 0 to 3.

6. A method according to claim 5, wherein said halogermane is selected from the group consisting of chlorogermane, dichlorogermane, and trichlorogermane.

7. A method according to claim 1, wherein said halogermane is a halodigermane according to the formula X₃₋ₘHₘGeGeHₙX₃₋ₙ, where X is F, Cl, Br, or I, m is 0 to 3 and n is 0 to 3.

8. A method according to claim 1, wherein said halogermane is an organogermane according to the formula R₄₋ₙGeHₙ, where R is a hydrocarbon group, and n is 0 to 3.

9. A method according to claim 1, wherein said halogermane is an organogermanium halide according to the formula R₄₋ₙGeXₙ, where R is a hydrocarbon group, X is F, Cl, Br, or I, and n is 1 to 3.

10. A method according to claim 1, further including the step of introducing a source of chlorine to said chamber.

11. A method according to claim 10, wherein said source of chlorine is Cl₂ or HCl.

12. A method according to claim 1, wherein said silane is selected from the group consisting of silane, disilane, trisilane, other higher order silanes, and organosilanes according to the formula R₄₋ₙSiHₙ, where R is a hydrocarbon group, and n is 0 to 3.

13. A method according to claim 1, wherein said steps of reacting and depositing comprises an epitaxial growth process selected from the group consisting of ultra-high vacuum CVD, low-pressure CVD, reduced-pressure CVD, rapid thermal CVD, and molecular beam epitaxy.

14. A method according to claim 1, wherein said halogermane and said silane are introduced to said chamber at a continuous rate between 1 sccm and 1000 sccm.

15. A method according to claim 1, wherein said chamber pressure is held between 1 mTorr and 10 Torr.

16. A method according to claim 1, wherein said semiconductor substrate is a silicon wafer, a silicon layer on an insulator (SOI) substrate, or a silicon surface exposed through a mask.

17. A method according to claim 1, wherein said SiGe layer comprises Si₁₋ₓGeₓ where x is 0 to 0.5.

18. A method according to claim 1, wherein said SiGe layer is selected from the group consisting of a relaxed layer, a graded layer, a strained layer or combinations thereof.

19. A method for forming a SiGeC layer on a semiconductor substrate, said method comprising:
providing a deposition chamber having said semiconductor substrate located therein;
introducing a halogermane precursor gas as a source material for germanium to said chamber;
introducing a silane precursor gas as a source material for silicon to said chamber;
introducing a carbon precursor gas as a source material for carbon to said chamber;
reacting said halogermane precursor, said silane precursor and said carbon precursor to create SiGeC;
depositing said SiGeC on to said semiconductor substrate.

20. A method according to claim 19, wherein said step of reacting is carried out in a temperature range of 100° C. to 1000° C.

21. A method according to claim 20, wherein said temperature range is 400° C. to 600° C.

22. A method according to claim 19, wherein said step of reacting is carried out at a temperature below 600° C.

23. A method according to claim 19, wherein said halogermane is a halogermane according to the formula X₄₋ₙGeHₙ, where X is F, Cl, Br, or I, and n is 0 to 3.

24. A method according to claim 23, wherein said halogermane is selected from the group consisting of chlorogermane, dichlorogermane, and trichlorogermane.

25. A method according to claim 19, wherein said halogermane is a halodigermane according to the formula X₃₋ₘHₘGeGeHₙX₃₋ₙ, where X is F, Cl, Br, or I, m is 0 to 3 and n is 0 to 3.

26. A method according to claim 19, wherein said halogermane is an organogermane according to the formula R₄₋ₙGeHₙ, where R is a hydrocarbon group, and n is 0 to 3.

27. A method according to claim 19, wherein said halogermane is an organogermanium halide according to the formula R₄₋ₙGeXₙ, where R is a hydrocarbon group, X is F, Cl, Br, or I, and n is 1 to 3.

28. A method according to claim 19, further including the step of introducing a source of chlorine to said chamber.

29. A method according to claim 28, wherein said source of chlorine is Cl₂ or HCl.

30. A method according to claim 19, wherein said silane is selected from the group consisting of silane, disilane, trisilane, other higher order silanes, and organosilanes according to the formula R₄₋ₙSiHₙ, where R is a hydrocarbon group, and n is 0 to 3.

31. A method according to claim 19, wherein said carbon precursor is selected from the group consisting of a hydrocarbon and monomethylsilane or other organosilanes.

32. A method according to claim 19, wherein said steps of reacting and depositing comprises an epitaxial growth process selected from the group consisting of ultra-high vacuum CVD, low-pressure CVD, reduced-pressure CVD, rapid thermal CVD, and molecular beam epitaxy.

33. A method according to claim 19, wherein said halogermane, said silane and said carbon are introduced to said chamber at a continuous rate between 1 sccm and 1000 sccm.

34. A method according to claim 19, wherein said chamber pressure is held between 1 mTorr and 10 Torr.

35. A method according to claim 19, wherein said semiconductor substrate is a silicon wafer, a silicon layer on an insulator (SOI) substrate, or a silicon surface exposed through a mask.

36. A method according to claim 19, wherein said SiGeC layer comprises Si_{1-x-y}GeₓC_{y} where x is 0 to 0.5 and y is 0 to 0.3.

37. A method according to claim 19, wherein said SiGeC layer is selected from the group consisting of a relaxed layer, a graded layer, a strained layer or combinations thereof.

38. A SiGe layer resulting from the reaction of a halogermane and a silane.

39. A SiGeC layer resulting from the reaction of a halogermane, a silane and a carbon precursor.

40. A semiconductor device including a SiGe layer, said SiGe layer formed from a reaction of a halogermane and a silane.

41. A semiconductor device including a SiGeC layer, said SiGeC layer formed from a reaction of a halogermane, a silane and a carbon precursor.

42. A silicon substrate having a SiGe layer formed thereon, said SiGe layer formed from a reaction of a halogermane and a silane.

43. A substrate according to claim 42, further including a mask and wherein said SiGe layer is selective formed over portions of said substrate that are exposed through said mask.

44. A silicon substrate including a SiGeC layer, said SiGeC layer formed from a reaction of a halogermane, a silane and a carbon precursor.

45. A substrate according to claim 44, further including a mask and wherein said SiGeC layer is selective formed over portions of said substrate that are exposed through said mask.

46. A SiGe layer formed at a reaction temperature lower than 600° C.

47. A SiGeC layer formed at a reaction temperature lower than 600° C.
